(19) United States
(12) Patent Application Publication
(10) Pub. No.: US 2026/0312488 A1
(43) Pub. Date: Oct. 8, 2026

(54) POWER SUPPLY CIRCUIT

(71) Applicant: ASUSTeK COMPUTER INC., Taipei City (TW)

(72) Inventors: Yu-Kai Yeh, Taipei City (TW); Wei-Gen Chung, Taipei City (TW); Hsiang-Jui Hung, Taipei City (TW); Hsi-Ho Hsu, Taipei City (TW); Chun-San Lin, Taipei City (TW); Chang-Tsai Tsai, Taipei City (TW); Ming-Ting Tsai, Taipei City (TW); Yu-Xuan Du, Taipei City (TW); Wei-Jhe Huang, Taipei City (TW)

(73) Assignee: ASUSTeK COMPUTER INC., Taipei City (TW)

(21) Appl. No.: 19/630,487

(22) Filed: Mar. 27, 2026

(30) Foreign Application Priority Data
Apr. 8, 2025 (TW) 114113128

(51) Int. Cl. H02M 1/32; G01K 7/22; G01R 19/165; H02M 1/36; H02M 3/158

(52) U.S. Cl. CPC H02M 1/327; G01K 7/22; G01R 19/16538; H02M 1/36; H02M 3/158

(57) ABSTRACT

A power supply circuit adapted for an electronic device is provided. The power supply circuit comprises an input interface, a charging circuit, a switching circuit, and a protection circuit. The input interface is configured to receive a power voltage. The charging circuit is configured to convert the received power voltage into a system voltage, and provide the system voltage to a system power terminal. The switching circuit is coupled between the input interface and the charging circuit, and configured to be controlled by a control signal to be turned on or off. The protection circuit is configured to adjust the control signal provided to the switching circuit according to the system voltage fed back from the system power terminal, thereby controlling the switching circuit.

### CROSS-REFERENCE TO RELATED APPLICATION

This application claims the priority benefit of Taiwan application serial no. 114113128, filed on Apr. 8, 2025. The entirety of the above-mentioned patent application is hereby incorporated by reference herein and made a part of this specification.

### BACKGROUND

### Technical Field

The disclosure relates to a power supply circuit capable of real-time detection of back-end system voltage.

### Description of Related Art

Today's electronic products emphasizing powerful performance (in an embodiment, artificial intelligence personal computers (AI PC) and gaming laptops) require greater computing performance. In order to comply with the Extended Power Range (EPR) specification of the USB Association, if the USB Type-C PD (Power Delivery) method used exceeds 100 watts (20 volts/5 amperes), it is necessary to change the approach from increasing the current to increasing the voltage. Taking the input of 28 volts power voltage via Type-C interface as an example, the maximum power can support up to 140 watts. However, in the situation of increased power voltage, when components in the charger architecture (especially narrow voltage direct current, NVDC charger architecture) experience abnormalities (equivalent to short circuit), voltage exceeding expectations will flow into the back-end system, creating a risk of burning for both chips and other passive components.

### SUMMARY

The disclosure provides a power supply circuit adapted for an electronic device. The power supply circuit comprises an input interface, a charging circuit, a switching circuit, and a protection circuit. The input interface is configured to receive a power voltage. The charging circuit is configured to convert the received power voltage into a system voltage, and provide the system voltage to a system power terminal. The switching circuit is coupled between the input interface and the charging circuit, and configured to be controlled by a control signal to be turned on or off. The protection circuit is coupled to the switching circuit and the system power terminal, and configured to adjust the control signal provided to the switching circuit according to the system voltage fed back from the system power terminal, thereby controlling the switching circuit.

Based on the above, the power supply circuit of the disclosure detects the magnitude of the back-end system voltage in real time and stops providing power in the situation of over-voltage. In this way, even when greater computing performance is required, situations where system components are burned is avoided, thereby achieving a protective effect.

In order to make the above-mentioned features and advantages of the disclosure clearer and easier to understand, the following embodiments are given and described in details with the accompanying drawings as follows.

### BRIEF DESCRIPTION OF THE DRAWINGS

FIG. 1 is a schematic circuit diagram of a power supply circuit drawn according to an embodiment of the disclosure.

FIG. 2 is a schematic circuit diagram of a charging circuit drawn according to an embodiment of the disclosure.

FIG. 3 is a schematic circuit diagram of a protection circuit drawn according to an embodiment of the disclosure.

FIG. 4 is a schematic circuit diagram of a protection circuit drawn according to another embodiment of the disclosure.

### DESCRIPTION OF THE EMBODIMENTS

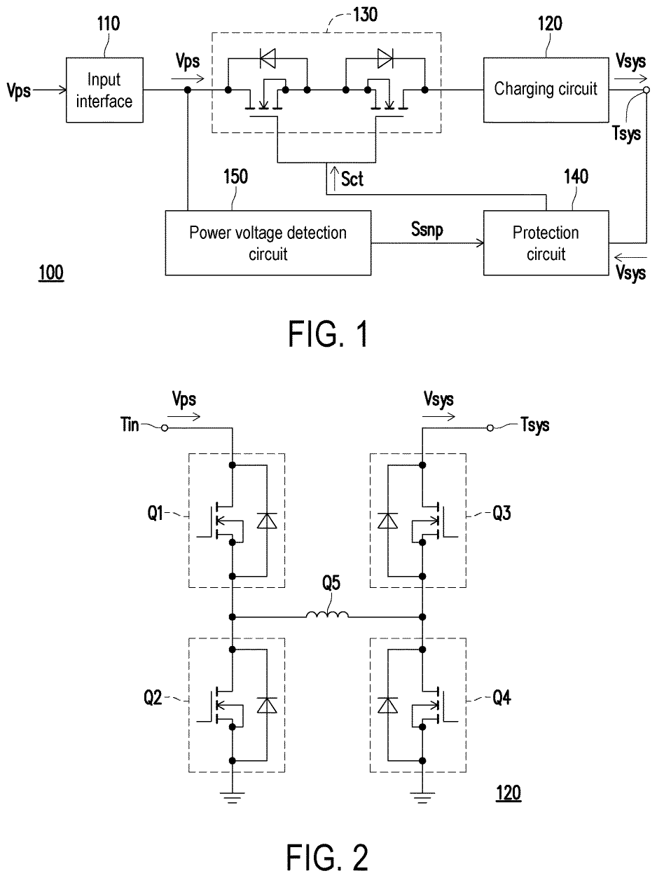

Please refer to FIG. 1 at the same time. A power supply circuit 100 of this embodiment is adapted for electronic devices such as personal computers, notebook computers, tablet computers, smartphones, personal digital assistants (PDA), and smart televisions, and other electronic products. The power supply circuit 100 comprises an input interface 110, a charging circuit 120, a switching circuit 130, a protection circuit 140, and a power voltage detection circuit 150.

In one embodiment, the input interface 110 is used for connecting to a power adapter such as a PD adapter (supplying power in USB Type-C PD method) to receive a power voltage Vps from the power adapter. The power voltage Vps is, in an embodiment, 28 volts.

In one embodiment, the charging circuit 120 converts the received power voltage Vps into a system voltage Vsys, and provides the system voltage Vsys to a system power terminal Tsys. In an embodiment, as shown in FIG. 2, the charging circuit 120 is an NVDC charger architecture, comprising a first charging component Q1, a second charging component Q2, a third charging component Q3, a fourth charging component Q4, and a fifth charging component Q5. A first terminal of the first charging component Q1 is coupled to an input terminal Tin. The input terminal Tin is configured to receive the power voltage Vps from the switching circuit 130 when the switching circuit 130 is turned on. A first terminal of the second charging component Q2 is coupled to a second terminal of the first charging component Q1, and a second terminal of the second charging component Q2 is grounded. A first terminal of the third charging component Q3 is coupled to the system power terminal Tsys. A first terminal of the fourth charging component Q4 is coupled to a second terminal of the third charging component Q3, and a second terminal of the fourth charging component Q4 is grounded. A first terminal of the fifth charging component Q5 is coupled to the second terminal of the first charging component Q1, and a second terminal of the fifth charging component Q5 is coupled to the second terminal of the third charging component Q3. Each charging component in the charging circuit 120 is controlled by a charger IC to be turned on or off in an embodiment, so as to convert the power voltage Vps into the system voltage Vsys according to current requirements.

In one embodiment, the fifth charging component Q5 is implemented by an inductor and the first to fourth charging components Q1-Q4 is implemented by n-type metal-oxide-semiconductor field-effect transistors (NMOSFET). However, the disclosure is not limited thereto, and in other embodiments, p-type metal-oxide-semiconductor field-effect transistors (PMOSFET) are also used for implementation.

In one embodiment, the system power terminal Tsys transmits the system voltage Vsys to the central processing unit (CPU), graphics processing unit (GPU), and other system components (various chips or passive components) on the motherboard, in an embodiment, via a voltage regulator. However, the disclosure is not limited thereto.

Please refer back to FIG. 1. The switching circuit 130 is coupled between the input interface 110 and the charging circuit 120. In one embodiment, the switching circuit 130 is controlled by a control signal Sct to be turned on or off. When the control signal Sct is at a first logic level (in an embodiment, high logic level), the switching circuit 130 is turned on to provide the power voltage Vps to the charging circuit 120. When the control signal Sct is at a second logic level (in an embodiment, low logic level), the switching circuit 130 is turned off to stop providing the power voltage Vps to the charging circuit 120. However, the disclosure is not limited thereto.

In one embodiment, the switching circuit 130 is implemented by two back-to-back n-type metal-oxide-semiconductor field-effect transistors. In other embodiments, p-type metal-oxide-semiconductor field-effect transistors are also used for implementation. However, the disclosure is not limited thereto.

The protection circuit 140 is coupled to the switching circuit 130 and the system power terminal Tsys. In one embodiment, the protection circuit 140 adjusts the control signal Sct provided to the switching circuit 130 according to the system voltage Vsys fed back from the system power terminal Tsys, thereby controlling the switching circuit 130.

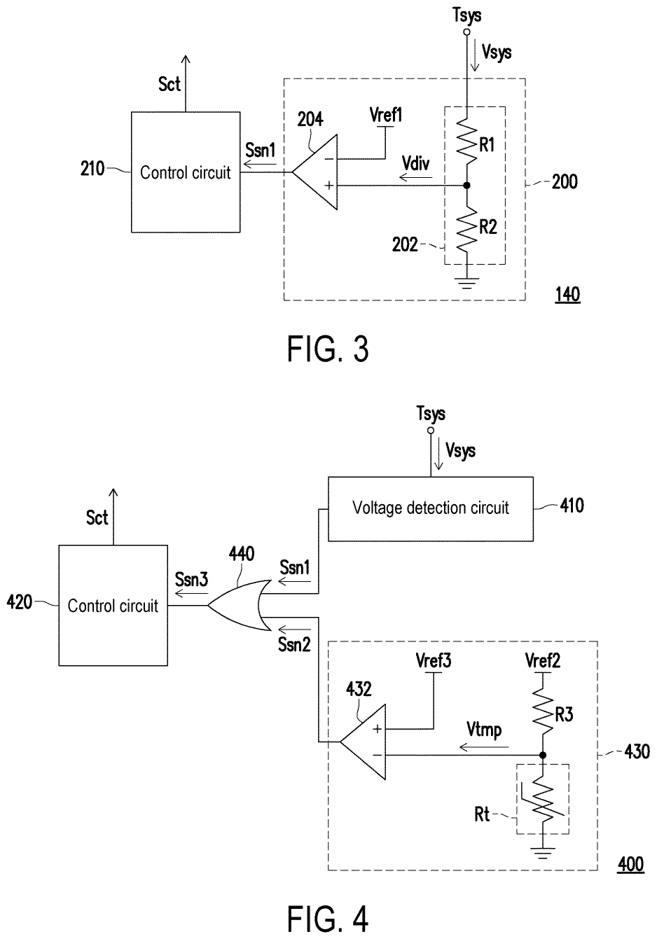

In an embodiment, as shown in FIG. 3, the protection circuit 140 comprises a voltage detection circuit 200 and a control circuit 210. The voltage detection circuit 200 detects the system voltage Vsys on the system power terminal Tsys, and generates a first detection signal Ssn1 according to the system voltage Vsys. The control circuit 210 is coupled to the voltage detection circuit 200. The control circuit 210 provides the control signal Sct to the switching circuit 130 according to the first detection signal Ssn1. The control circuit 210 is implemented by a logic circuit composed of multiple logic gates. However, the disclosure is not limited thereto.

Specifically, the voltage threshold value is the maximum voltage safety value that the system components behind the system power terminal Tsys may withstand. When the system voltage Vsys is less than the voltage threshold value, it indicates that there is no risk of the system components being burned. At this time, the voltage detection circuit 200 generates the first detection signal Ssn1 with a second logic level. The control circuit 210 responds to the first detection signal Ssn1 with the second logic level by maintaining the control signal Sct at a first logic level, so as to keep the switching circuit 130 continuously turned on.

When the system voltage Vsys is greater than the voltage threshold value, it indicates that there is a risk of the system components being burned. At this time, the voltage detection circuit 200 generates the first detection signal Ssn1 with a first logic level. The control circuit 210 responds to the first detection signal Ssn1 with the first logic level by converting the control signal Sct from the first logic level to a second logic level, so as to immediately turn off the switching circuit 130.

More specifically, the voltage detection circuit 200 comprises a voltage divider circuit 202 and a first comparator 204. The voltage divider circuit 202 comprises a first resistor R1 and a second resistor R2. A first terminal of the first resistor R1 receives the system voltage Vsys from the system power terminal Tsys. A first terminal of the second resistor R2 is coupled to a second terminal of the first resistor R1, and a second terminal of the second resistor R2 is grounded. The voltage divider circuit 202 divides the system voltage Vsys to output a divided voltage Vdiv from the second terminal of the first resistor R1.

The above-mentioned voltage threshold value is calculated by the following formula (1) in an embodiment:

$$V ths = 1.22 * ( 1 + \frac{R 1}{R 2} ) \qquad ( 1 )$$

where, Vths is a voltage threshold value, R1 is a resistance value of the first resistor R1, R2 is a resistance value of the second resistor R2. In an embodiment, the resistance value of the first resistor R1 is 100k ohm, the resistance value of the second resistor R2 is 5.6k ohm, and the voltage threshold value is approximately 23 volt.

A non-inverting input terminal of the first comparator 204 receives the divided voltage Vdiv, and an inverting input terminal of the first comparator 204 receives a first reference voltage Vref1. The first comparator 204 compares the divided voltage Vdiv with the first reference voltage Vref1, and outputs the first detection signal Ssn1 at its output terminal according to the comparison result. The first reference voltage Vref1 depends on the above-mentioned voltage threshold value and the resistance value distribution of the voltage divider circuit 202. In the situation where the voltage threshold value is approximately 23 volt, the first reference voltage Vref1 is, in an embodiment, approximately 1.22 volt.

When the divided voltage Vdiv is greater than the first reference voltage Vref1, which is equivalent to the system voltage Vsys being greater than the voltage threshold value, the first comparator 204 outputs the first detection signal Ssn1 with the first logic level. When the divided voltage Vdiv is less than the first reference voltage Vref1, which is equivalent to the system voltage Vsys being less than the voltage threshold value, the first comparator 204 outputs the first detection signal Ssn1 with the second logic level.

Through the above operation, the power supply circuit 100 detects the back-end system voltage Vsys in real-time, and stops providing power when there is a risk of the system component being burned, thereby achieving an over-voltage protection effect.

The power voltage detection circuit 150 is coupled to the input interface 110 and the protection circuit 140. The power voltage detection circuit 150 detects the power voltage Vps, and generates a power-side detection signal Ssnp according to the power voltage Vps. The control circuit 210 in the protection circuit 140 receives the power-side detection signal Ssnp, and adjusts the control signal Sct according to the power-side detection signal Ssnp.

Specifically, the power-side voltage threshold value is the maximum voltage safety value of the power voltage Vps. When the power voltage Vps is greater than the power-side voltage threshold value, it indicates that there is a risk of the system component being burned. At this time, the power voltage detection circuit 150 generates the power-side detection signal Ssnp with a first logic level. The control circuit 210 in the protection circuit 140 also responds to the power-side detection signal Ssnp with the first logic level by converting the control signal Sct from the first logic level to a second logic level, so as to immediately turn off the switching circuit 130. It should be noted that the internal circuit structure of the power voltage detection circuit 150 is implemented with the same or similar implementation method as the voltage detection circuit 200, which will not be described again here.

In another implementation, the protection circuit also controls the switching circuit 130 according to the temperature of one or more detection points. Specifically, referring to FIG. 4, a protection circuit 400 comprising a voltage detection circuit 410 and a control circuit 420 replaces the protection circuit 140 to function in the power supply circuit 100. The voltage detection circuit 410 detects the system voltage Vsys on the system power terminal Tsys, and generates the first detection signal Ssn1 according to the system voltage Vsys. The internal circuit structure and operation details of the voltage detection circuit 410 are the same as or similar to those of the voltage detection circuit 200 in the aforementioned implementation, which will not be described again here.

Different from the aforementioned implementation, the protection circuit 400 further comprises a temperature detection circuit 430 and an OR gate 440. The temperature detection circuit 430 detects the temperature of the detection point set in the electronic device, and generates a second detection signal Ssn2 according to the temperature of the detection point. A first input terminal of the OR gate 440 receives the first detection signal Ssn1, and a second input terminal of the OR gate 440 receives the second detection signal Ssn2. The OR gate 440 performs an OR operation on the first detection signal Ssn1 and the second detection signal Ssn2 to output a third detection signal Ssn3 at its output terminal to the control circuit 420.

Specifically, the detection point, in an embodiment, is set at a position close to the diode formed by the first charging component Q1 in the charging circuit 120. The temperature threshold value is the maximum temperature safety value that the components around the detection point (in an embodiment, the first charging component Q1) can withstand. When the temperature of the detection point is less than the temperature threshold value, it indicates that there is no risk of damage due to high temperature for the components around the detection point. At this time, the temperature detection circuit 430 generates the second detection signal Ssn2 with a second logic level. Thus, in the situation where the first detection signal Ssn1 is also at the second logic level, the OR gate 440 will output the third detection signal Ssn3 with the second logic level to the control circuit 420. The control circuit 420 then responds to the third detection signal Ssn3 with the second logic level by maintaining the control signal Sct at a first logic level, to keep the switching circuit 130 continuously turned on.

When the temperature of the detection point is greater than the temperature threshold value, it indicates that there is a risk of damage due to high temperature for the components around the detection point. At this time, the temperature detection circuit 430 generates the second detection signal Ssn2 with a first logic level. Thus, regardless of whether the first detection signal Ssn1 is at the first logic level or the second logic level, the OR gate 440 will output the third detection signal Ssn3 with the first logic level to the control circuit 420. The control circuit 420 then responds to the third detection signal Ssn3 with the first logic level by converting the control signal Sct from the first logic level to a second logic level, so as to immediately turn off the switching circuit 130.

More specifically, the temperature detection circuit 430 comprises a third resistor R3, a thermistor Rt, and a second comparator 432. A first terminal of the third resistor R3 receives a second reference voltage Vref2. A first terminal of the thermistor Rt is coupled to a second terminal of the third resistor R3, and a second terminal of the thermistor Rt is grounded. The third resistor R3 and the thermistor Rt divide the second reference voltage Vref2 to output a temperature voltage Vtmp from the second terminal of the third resistor R3. The second reference voltage Vref2 is, in an embodiment, 5 volts, and the third resistor R3 is, in an embodiment, 61k ohms. The thermistor Rt is, in an embodiment, a negative temperature coefficient (NTC) thermistor, whose resistance value decreases with rising temperature, in an embodiment, starting from 100k ohms.

A non-inverting input terminal of the second comparator 432 receives a third reference voltage Vref3, and an inverting input terminal of the second comparator 432 receives the temperature voltage Vtmp. The second comparator 432 compares the temperature voltage Vtmp with the third reference voltage Vref3, and outputs the second detection signal Ssn2 at its output terminal according to the comparison result. The third reference voltage Vref3 depends on the temperature threshold value mentioned above and the resistance value distribution between the third resistor R3 and the thermistor Rt, and is, in an embodiment, approximately 1.22 volts.

When the temperature voltage Vtmp is less than the third reference voltage Vref3, which is equivalent to the temperature of the detection point being greater than the temperature threshold value, the second comparator 432 outputs the second detection signal Ssn2 with the first logic level. When the temperature voltage Vtmp is greater than the third reference voltage Vref3, which is equivalent to the temperature of the detection point being less than the temperature threshold value, the second comparator 432 outputs the second detection signal Ssn2 with the second logic level.

It should be noted that, although this embodiment is explained with a protection circuit 400 comprising one temperature detection circuit 430, the disclosure is not limited thereto. Those skilled in the art may, according to their actual needs and with reference to the teachings of this embodiment, increase the number of the temperature detection circuits by incorporating additional detection points at various locations.

In summary, the power supply circuit of the disclosure detects the magnitude of the back-end system voltage and the temperature of the pre-set detection points in real time and stops providing power in situations of over-voltage or over-temperature. In this way, even when greater computing performance is required, situations where system components are burned or damaged due to high temperature is avoided, thereby achieving a protective effect.

What is claimed is:

1. A power supply circuit, adapted for an electronic device, wherein the power supply circuit comprises:
an input interface, configured to receive a power voltage;
a charging circuit, configured to convert the received power voltage into a system voltage, and provide the system voltage to a system power terminal;
a switching circuit, coupled between the input interface and the charging circuit, and configured to be controlled by a control signal to be turned on or off; and
a protection circuit, coupled to the switching circuit and the system power terminal, and configured to adjust the control signal provided to the switching circuit according to the system voltage fed back from the system power terminal, thereby controlling the switching circuit.

2. The power supply circuit according to claim 1, wherein the protection circuit comprises:
a voltage detection circuit, configured to detect the system voltage on the system power terminal, and generate a first detection signal according to the system voltage; and
a control circuit, coupled to the voltage detection circuit, and configured to provide the control signal to the switching circuit according to the first detection signal.

3. The power supply circuit according to claim 2, wherein when the system voltage is greater than a voltage threshold value, the voltage detection circuit generates the first detection signal with a first logic level, and
the control circuit responds to the first detection signal with the first logic level by converting the control signal from the first logic level to a second logic level, so as to turn off the switching circuit.

4. The power supply circuit according to claim 2, wherein the voltage detection circuit comprises:
a voltage divider circuit, configured to receive the system voltage, and divide the system voltage to output a divided voltage; and
a first comparator, wherein a non-inverting input terminal of the first comparator receives the divided voltage, an inverting input terminal of the first comparator receives a first reference voltage, and an output terminal of the first comparator outputs the first detection signal.

5. The power supply circuit according to claim 4, wherein the voltage divider circuit comprises:
a first resistor, wherein a first terminal of the first resistor receives the system voltage, and a second terminal of the first resistor outputs the divided voltage; and
a second resistor, wherein a first terminal of the second resistor is coupled to the second terminal of the first resistor, and a second terminal of the second resistor is grounded.

6. The power supply circuit according to claim 2, wherein the protection circuit further comprises:
a temperature detection circuit, configured to detect a temperature of a detection point in the electronic device, and generate a second detection signal according to the temperature of the detection point; and
an OR gate, wherein a first input terminal of the OR gate receives the first detection signal, a second input terminal of the OR gate receives the second detection signal, and an output terminal of the OR gate outputs a third detection signal to the control circuit.

7. The power supply circuit according to claim 6, wherein when the temperature of the detection point is greater than a temperature threshold value, the temperature detection circuit generates the second detection signal with a first logic level, and
the control circuit responds to the third detection signal with the first logic level by converting the control signal from the first logic level to a second logic level, so as to turn off the switching circuit.

8. The power supply circuit according to claim 6, wherein the temperature detection circuit comprises:
a third resistor, wherein a first terminal of the third resistor receives a second reference voltage, and a second terminal of the third resistor outputs a temperature voltage;
a thermistor, wherein a first terminal of the thermistor is coupled to the second terminal of the third resistor, and a second terminal of the thermistor is grounded; and
a second comparator, wherein a non-inverting input terminal of the second comparator receives a third reference voltage, an inverting input terminal of the second comparator receives the temperature voltage, and an output terminal of the second comparator outputs the second detection signal.

9. The power supply circuit according to claim 2, further comprising:
a power voltage detection circuit, coupled to the input interface and the protection circuit, and configured to detect the power voltage, and generate a power-side detection signal according to the power voltage,
wherein the control circuit receives the power-side detection signal, and adjusts the control signal according to the power-side detection signal.

10. The power supply circuit according to claim 1, wherein the charging circuit comprises:
a first charging component, wherein a first terminal of the first charging component is coupled to an input terminal, and the input terminal is configured to receive the power voltage;
a second charging component, wherein a first terminal of the second charging component is coupled to a second terminal of the first charging component, and a second terminal of the second charging component is grounded;
a third charging component, wherein a first terminal of the third charging component is coupled to the system power terminal;
a fourth charging component, wherein a first terminal of the fourth charging component coupled to a second terminal of the third charging component, and a second terminal of the fourth charging component is grounded; and
a fifth charging component, wherein a first terminal of the fifth charging component is coupled to the second terminal of the first charging component, and a second terminal of the fifth charging component is coupled to the second terminal of the third charging component.
